(19) United States
(12) Patent Application Publication
(10) Pub. No.: US 2024/0304459 A1
(43) Pub. Date: Sep. 12, 2024

(54) MANUFACTURING METHOD OF SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: SHUHEI ICHIKAWA, Nisshin-shi (JP); HIROKI MIYAKE, Nisshin-shi (JP); TATSUJI NAGAOKA, Nisshin-shi (JP)

(21) Appl. No.: 18/420,016

(22) Filed: Jan. 23, 2024

(30) Foreign Application Priority Data
Mar. 6, 2023 (JP) 2023-033930

(51) Int. Cl. H01L 21/385; H01L 21/02

(52) U.S. Cl. CPC H01L 21/385; H01L 21/02233

(57) ABSTRACT

In a manufacturing method of a semiconductor device, a semiconductor substrate made of β-gallium oxide and having a first surface or a second surface in a range of 45 to 90° with respect to a (100) plane or to a (001) plane is prepared. The semiconductor substrate is placed on a susceptor in a chamber so that the second surface faces the susceptor. The chamber is sealed, and a heat treatment is performed. In the heat treatment, a temperature of the semiconductor substrate is increased and then decreased by heat transfer by adjusting a temperature of the susceptor. The sealing of the chamber is then released. In the heat treatment, the temperature of the semiconductor substrate is increased to 300° C. or more by increasing a temperature of the susceptor at a temperature increase rate of 100° C./min or less.

### CROSS REFERENCE TO RELATED APPLICATION

The present application claims the benefit of priority from Japanese Patent Application No. 2023-033930 filed on Mar. 6, 2023. The entire disclosures of the above application are incorporated herein by reference.

### TECHNICAL FIELD

The present disclosure relates to a manufacturing method of a semiconductor device, in particular, a manufacturing method that includes performing a heat treatment of a substrate made of β-gallium oxide (i.e., Ga₂O₃).

### BACKGROUND

Conventionally, in a manufacturing method of a semiconductor device, it has been proposed to perform a heat treatment in order to activate an impurity implanted by ion implantation and to recover a defect in a semiconductor substrate. However, when a temperature difference between one surface and the other surface of the semiconductor substrate is large during the heat treatment, the semiconductor substrate may be warped and broken. Therefore, for example, in a case where a silicon substrate is used as the semiconductor substrate and the semiconductor substrate is subjected to the heat treatment, it has been proposed a technique of rapidly increasing the temperature of the semiconductor substrate to about 500 degrees Celsius (° C.) and then slowly increasing the temperature of the semiconductor substrate to about 1000° C.

In recent years, β-gallium oxide having a larger band gap energy than silicon carbide or the like has attracted attention, and it has been studied to form a semiconductor device having a semiconductor element such as a metal oxide semiconductor field effect transistor (MOSFET) using a semiconductor substrate made of β-gallium oxide.

### SUMMARY

The present disclosure describes a manufacturing method of a semiconductor device. According to an aspect of the present disclosure, a manufacturing method of a semiconductor device includes: preparing a semiconductor substrate made of β-gallium oxide; placing the semiconductor substrate on a susceptor disposed in a chamber; sealing the chamber; performing a heat treatment of increasing a temperature of the semiconductor substrate and then decreasing the temperature of the semiconductor substrate by heat transfer by adjusting a temperature of the susceptor; and releasing the sealing of the chamber to enable the semiconductor substrate to be taken out of the chamber. In the preparing, the semiconductor substrate in which a first surface or a second surface opposite to the first surface is in a range of 45° to 90° with respect to a (100) plane or in a range of 45° to 90° with respect to a (001) plane is prepared. In the placing, the semiconductor substrate is placed so that the second surface faces the susceptor. In the performing of the heat treatment, the temperature of the semiconductor substrate is increased to 300° C. or more by increasing a temperature of the susceptor under a condition that a temperature increase rate of the susceptor is 100° C./min or less.

### BRIEF DESCRIPTION OF THE DRAWINGS

Objects, features and advantages of the present disclosure will become more apparent from the following detailed description made with reference to the accompanying drawings, in which:

FIG. 1 is a cross-sectional view of a heating apparatus for performing a heat treatment according to a first embodiment of the present disclosure; and

FIG. 2 is a diagram illustrating a relationship between an elapsed time and a setting temperature of a susceptor.

### DETAILED DESCRIPTION

To begin with, a relevant technology will be described only for understanding the embodiments of the present disclosure.

It has been reported that β-gallium oxide has a monoclinic crystal structure and has a low thermal conductivity of about one sixth of silicon. Further, there is a report suggesting that the linear expansion coefficient of β-gallium oxide in the direction sharply decreases around 300° C.

The inventors of the present disclosure have been studying the configuration of a semiconductor device using a β-gallium oxide substrate as a semiconductor substrate. However, as described above, since β-gallium oxide has a low thermal conductivity, a temperature difference is likely to occur between one surface and the other surface, which is opposite to the one surface, of the semiconductor substrate when the semiconductor substrate is subjected to the heat

treatment. In addition, the linear expansion coefficient of β-gallium oxide in the direction sharply decreases around 300° C. In the case where the β-gallium oxide substate is used as the semiconductor substrate, when the one surface or the other surface of the semiconductor substrate is in the range of 45° to 90° with respect to the (100) plane or in the range of 45° to 90° with respect to the (001) plane, the semiconductor substrate has the planar direction along the direction.

Therefore, in the case where β-gallium oxide is used for the semiconductor substrate and the one surface or the other surface of the semiconductor substrate is within the range of 45° to 90° with respect to the (100) plane or the (001) plane, if the heat treatment at 300° C. or higher is performed in the same manner as in the case of the silicon substrate, the following phenomenon is likely to occur. That is, since the thermal conductivity is low, the temperature difference between the one surface and the other surface of the semiconductor substrate is likely to be large. In addition, since the planar direction of the semiconductor substrate is the direction, the possibility that the semiconductor substrate warps and fractures will increase.

The present disclosure provides a manufacturing method of a semiconductor device having a semiconductor substrate made of β-gallium oxide, which is capable of suppressing breakage of the semiconductor substrate even when a heat treatment is performed.

According to an aspect of the present disclosure, a manufacturing method of a semiconductor device includes: preparing a semiconductor substrate made of β-gallium oxide; placing the semiconductor substrate on a susceptor disposed in a chamber; sealing the chamber; performing a heat treatment of increasing a temperature of the semiconductor substrate and then decreasing the temperature of the semiconductor substrate by heat transfer by adjusting a temperature of the susceptor; and releasing the sealing of the chamber to enable the semiconductor substrate to be taken out of the chamber. In the preparing of the semiconductor substrate, the semiconductor substrate in which a first surface or a second surface opposite to the first surface is in a range of 45° to 90° with respect to a (100) plane or in a range of 45° to 90° with respect to a (001) plane is prepared. In the placing of the semiconductor substrate, the semiconductor substrate is placed so that the second surface faces the susceptor. In the performing of the heat treatment, the temperature of the semiconductor substrate is increased to 300° C. or more by increasing the temperature of the susceptor under a condition in which a temperature increase rate of the susceptor is 100° C./min or less.

According to such a manufacturing method, when the temperature of the semiconductor substrate is increased, a temperature difference is less likely to occur between the first surface and the second surface of the semiconductor substrate. As such, it is less likely that the semiconductor substrate will be broken.

Embodiments of the present disclosure will be described hereinafter with reference to the drawings. In the following description, the same or equivalent parts are denoted by the same reference numerals throughout the embodiments.

### First Embodiment

A first embodiment will be described with reference to the drawings. Hereinafter, a manufacturing method of a semiconductor device that uses a semiconductor substrate made of β-gallium oxide and includes a heat treatment will be described.

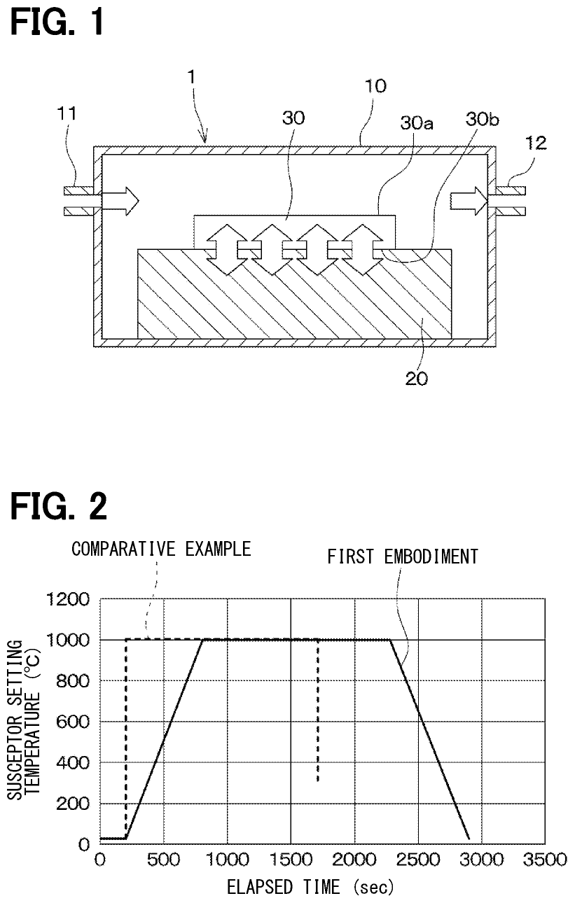

First, a configuration of a heating apparatus 1 for performing a heating treatment will be described with reference to FIG. 1. As shown in FIG. 1, the heating apparatus 1 includes a chamber 10 and a susceptor 20.

The chamber 10 is connected to an exhaust pump (not shown) or the like, and the inside of the chamber 10 is maintained at a predetermined pressure. The chamber 10 includes a supply port 11 through which an atmospheric gas is supplied and an exhaust port 12 through which the atmospheric gas is exhausted.

A semiconductor substrate 30 has a first surface 30a as one surface and a second surface 30b as the other surface opposite to the one surface. The susceptor 20 is configured to increase (i.e., heat) and decrease (i.e., cool) the temperature of the semiconductor substrate 30 placed on the susceptor 20. Specifically, the susceptor 20 is configured to increase and decrease the temperature of the semiconductor substrate 30 by heat transfer. For example, the susceptor 20 is made of a material, such as graphite or silicon carbide, which has high thermal conductivity. The temperature of the susceptor 20 is adjusted by, for example, lamp heating or induction heating.

The heating apparatus 1 of the present embodiment has the configurations as described above. Next, a method for manufacturing a semiconductor device, which includes a heat treatment using the heating apparatus 1, will be described.

First, as the semiconductor substrate 30, a semiconductor substrate made of β-gallium oxide and having a direction along the planar direction of the first surface 30a or the second surface 30b is prepared. More specifically, as the semiconductor substrate 30, a semiconductor substrate made of β-gallium oxide and in which the first surface 30a or the second surface 30b is in a range of 45° to 90° with respect to a (100) plane or a semiconductor substrate made of β-gallium oxide and in which the first surface 30a or the second surface 30b is in a range of 45° to 90° with respect to a (001) plane is prepared.

For example, the semiconductor substrate 30 may be a substrate into which an impurity providing an impurity layer, which constitutes a semiconductor element, is ion-implanted. Examples of the impurity to be ion-implanted include nitrogen, zinc, and magnesium in the case of forming a p-type impurity layer. For example, the semiconductor substrate 30 may be formed with a trench for forming a trench gate structure on the first surface 30a side.

Then, the semiconductor substrate 30 is placed on the susceptor 20 such that the second surface 30b faces the susceptor 20. Thereafter, the chamber 10 is sealed, and the inside of the chamber 10 is set to be at a predetermined pressure by an exhaust pump (not shown) or the like.

Next, the temperature of the susceptor 20 is adjusted, and a heat treatment is performed in which the temperature of the semiconductor substrate 30 is increased to 300° C. or more by heat transfer from the susceptor 20, and then the temperature of the semiconductor substrate 30 is decreased by heat transfer to the susceptor 20. In this case, as will be specifically described later, when the temperature of the semiconductor substrate 30 is increased, an occurrence of a temperature difference between the first surface 30a and the second surface 30b of the semiconductor substrate 30 can be suppressed by regulating a temperature increase rate of the susceptor 20. Similarly, as will be described in detail later, when the temperature of the semiconductor substrate 30 is decreased, an occurrence of the temperature difference between the first surface 30a and the second surface 30b of the semiconductor substrate 30 can be suppressed by regulating a temperature decrease rate of the susceptor 20.

The heat treatment is performed while supplying a predetermined atmospheric gas into the chamber 10 from the supply port 11 and exhausting the atmospheric gas from the exhaust port 12. For example, in the case where the heat treatment is performed for oxidizing the semiconductor substrate 30, the heat treatment is performed while supplying oxygen as the atmospheric gas. For example, in the case where the heat treatment is performed for diffusing an impurity implanted by ion-implantation without oxidizing the semiconductor substrate 30, the heat treatment is performed while supplying nitrogen or argon as the atmospheric gas.

After the temperature of the susceptor 20 is decreased to a predetermined temperature, the sealed state of the chamber 10 is released, so that the semiconductor substrate 30 can be taken out.

Thereafter, a predetermined manufacturing process is performed to form predetermined electrodes and the like. In this way, a desired semiconductor device is manufactured.

The method for manufacturing a semiconductor device including the heat treatment according to the present embodiment has been described hereinabove. Next, the results actually obtained by the inventors of the present disclosure will be described.

First, as the semiconductor substrate 30, a semiconductor substrate having a size of 2 inches and a thickness of 400 μm was prepared. As described above, the semiconductor substrate 30 was made of β-gallium oxide, and has the direction along the planar direction of the first surface 30a or the second surface 30b.

Then, the inventors of the present disclosure performed a heat treatment as shown in FIG. 2. In FIG. 2, the flow rate of the nitrogen gas as the atmospheric gas is 2 slm (standard litter min).

Specifically, when the temperature of the semiconductor substrate 30 was increased, the temperature increase rate of the susceptor 20 was set to 100° C./min so as to secure a sufficient heat transfer time in the semiconductor substrate 30 and not to generate a large temperature difference between the first surface 30a and the second surface 30b of the semiconductor substrate 30. Then, the temperature of the susceptor 20 was maintained at 1000° C. for about 10 minutes. Thereafter, when the temperature of the semiconductor substrate 30 is decreased, the temperature decrease rate of the susceptor 20 was set to 100° C./min so as not to generate a large temperature difference between the first surface 30a and the second surface 30b of the semiconductor substrate 30. Then, after the temperature of the susceptor 20 was decreased to 100° C. or less so that the semiconductor substrate 30 could be taken out, the sealed state of the chamber 10 was released and the semiconductor substrate 30 was taken out.

In the present embodiment, although the heat treatment is performed while supplying the atmospheric gas to the chamber 10, the first surface 30a side of the semiconductor substrate 30 is restricted from being cooled by the atmospheric gas. In the present embodiment, the semiconductor substrate 30 is exposed to the atmospheric gas heated by the heat of the susceptor 20. Specifically, according to the study of the inventors of the present disclosure, it was confirmed that the first surface 30a side of the semiconductor substrate 30 is hardly cooled by the atmospheric gas by controlling the flow rate of the supplied atmospheric gas such that the exchange rate of the atmospheric gas in the chamber 10 per unit minute is 100% or less of the volume of the chamber 10. In the present embodiment, since the volume of the chamber 10 is 10 L and the flow rate of the nitrogen gas is 2 slm, the flow rate of the nitrogen gas is 100% or less of the volume of the chamber 10.

The inventors of the present disclosure confirmed that the semiconductor substrate 30 was not fractured when the heat treatment of the semiconductor substrate 30 was performed under the above conditions.

On the other hand, in a comparative example, the temperature increase rate of the susceptor 20 was set to 6000° C./min, and the temperature of the susceptor 20 was maintained at 1000° C. for 10 minutes. In the comparative example, further, the temperature of the susceptor 20 was decreased to 300° C. at a temperature decrease rate of 6000° C./min, and the susceptor 20 was brought into a state so that the semiconductor substrate 30 can be taken out. Then, the semiconductor substrate 30 was taken out.

The inventors of the present disclosure confirmed that the semiconductor substrate 30 fractured when the semiconductor substrate 30 was subjected to the heat treatment under the conditions of the comparative example. Further, the inventors of the present disclosure found that the fracture occurred along the [010] direction. The [010] direction is a direction inclined by 90° with respect to the [100] direction in which distortion due to a temperature difference between the first surface 30a and the second surface 30b is likely to occur. Therefore, it is considered that the linear expansion coefficient in the [100] direction affects the heat treatment of β-gallium oxide.

As described above, in the present embodiment, the temperature of the semiconductor substrate 30 is increased under the condition that the temperature increase rate of the susceptor 20 is 100° C./min or less. Therefore, when the temperature of the semiconductor substrate 30 is increased, a temperature difference is less likely to occur between the first surface 30a and the second surface 30b of the semiconductor substrate 30, and the semiconductor substrate 30 can be suppressed from fracturing.

(1) In the present embodiment, the temperature of the semiconductor substrate 30 is decreased under the condition that the temperature decrease rate of the susceptor 20 is 100° C./min or less. Therefore, when the temperature of the semiconductor substrate 30 is decreased, a temperature difference is less likely to occur between the first surface 30a and the second surface 30b of the semiconductor substrate 30, and the semiconductor substrate 30 can be suppressed from fracturing.

(2) In the present embodiment, the temperature of the susceptor 20 is decreased to 100° C. or less to bring the susceptor 20 to the state that enables the semiconductor substrate 30 to be taken out. Therefore, when the semiconductor substrate 30 is taken out, it is possible to suppress the semiconductor substrate 30 from fracturing due to a temperature difference with the outside air.

(3) In the present embodiment, the semiconductor substrate 30 is exposed to a heated atmospheric gas. Therefore, it is possible to suppress the first surface 30a side of the semiconductor substrate 30 from being cooled by the atmospheric gas, and it is possible to suppress the temperature difference between the first surface 30a and the second surface 30b from increasing.

(4) In the present embodiment, the flow rate of the atmospheric gas is controlled such that the gas exchange rate in the chamber 10 per unit minute is 100% or less of the volume of the chamber 10. Therefore, it is possible to restrict the first surface 30a side of the semiconductor substrate 30 from being cooled by the atmospheric gas, and it is possible to suppress the temperature difference between the first surface 30a and the second surface 30b from increasing.

(5) In the present embodiment, for example, the semiconductor substrate 30 has a size of 2 inches in diameter and a thickness of 400 μm, so that the semiconductor substrate 30 is restricted from fracturing when being subjected to the heat treatment. As the thickness of the semiconductor substrate 30 decreases, a temperature difference is less likely to occur between the first surface 30a and the second surface 30b. That is, the same result as described above can be achieved as long as the semiconductor substrate 30 has the thickness of 400 μm or less.

### Other Embodiments

Although the present disclosure has been described in accordance with the embodiment(s), it is understood that the present disclosure is not limited to such embodiment(s) or structure(s). The present disclosure encompasses various modifications and variations within the scope of equivalents. In addition, various combinations and configurations, as well as other combinations and configurations that include only one element, more, or less, fall within the scope and spirit of the present disclosure.

For example, in the first embodiment described above, the atmospheric gas may be heated outside the chamber 10 and supplied into the chamber 10. Further, the flow rate and the like of the atmosphere gas can be appropriately changed as long as the first surface 30a side of the semiconductor substrate 30 is less likely to be cooled by the atmosphere gas.

In the first embodiment described above, the size and thickness of the semiconductor substrate 30 can be changed as appropriate.

While only the selected exemplary embodiments and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiments and examples according to the present disclosure is provided for illustration only, and not for the purpose of limiting the disclosure as defined by the appended claims and their equivalents.

What is claimed is:

1. A manufacturing method of a semiconductor device, the method comprising:
preparing a semiconductor substrate made of β-gallium oxide;
placing the semiconductor substrate on a susceptor disposed in a chamber;
sealing the chamber;
performing a heat treatment of increasing a temperature of the semiconductor substrate and then decreasing the temperature of the semiconductor substrate by heat transfer by adjusting a temperature of the susceptor; and
releasing the sealing of the chamber to enable the semiconductor substrate to be taken out of the chamber, wherein
in the preparing, the semiconductor substrate in which a first surface or a second surface opposite to the first surface is in a range of 45° to 90° with respect to a (100) plane or in a range of 45° to 90° with respect to a (001) plane is prepared,
in the placing, the semiconductor substrate is placed so that the second surface faces the susceptor; and
in the performing of the heat treatment, the temperature of the semiconductor substrate is increased to 300° C. or more by increasing a temperature of the susceptor under a condition that a temperature increase rate of the susceptor is 100° C./min or less.

2. The manufacturing method according to claim 1, wherein
in the performing of the heat treatment, the temperature of the semiconductor substrate is decreased to 300° C. or less by decreasing the temperature of the susceptor under a condition that a temperature decrease rate of the susceptor is 100° C./min.

3. The manufacturing method according to claim 2, wherein
the releasing includes decreasing the temperature of the susceptor to 100° C. or less.

4. The manufacturing method according to claim 1, wherein
the performing of the heat treatment includes supplying an atmospheric gas into the chamber, exhausting the atmospheric gas from the chamber, and exposing the semiconductor substrate to a heated atmospheric gas in the chamber.

5. The manufacturing method according to claim 4, wherein
the performing of the heat treatment includes adjusting a flow rate of the atmospheric gas such that an exchange rate of the atmospheric gas in the chamber per unit minute is 100% or less of a volume of the chamber.

6. The manufacturing method according to claim 1, wherein
in the preparing of the semiconductor substrate, the semiconductor substrate having a diameter of 2 inches is prepared.

7. The manufacturing method according to claim 1, wherein
in the preparing of the semiconductor substrate, the semiconductor substrate having a thickness of 400 μm or less between the first surface and the second surface is prepared.
